(19) United States
(12) Patent Application Publication
(10) Pub. No.: US 2026/0254423 A1
(43) Pub. Date: Aug. 27, 2026

(54) SWITCHING AMPLIFIERS

(71) Applicant: Cirrus Logic International Semiconductor Ltd., Edinburgh (GB)

(72) Inventors: John P. LESSO, Edinburgh (GB); John L. MELANSON, Austin, TX (US)

(73) Assignee: Cirrus Logic International Semiconductor Ltd., Edinburgh (GB)

(21) Appl. No.: 19/065,102

(22) Filed: Feb. 27, 2025

(51) Int. Cl. H03F 3/217

(52) U.S. Cl. CPC H03F 3/2173; H03F 2200/267; H03F 2203/21157

(57) ABSTRACT

This application relates to methods and apparatus for controlling a switching amplifier to drive a load with a differential drive signal based on an input signal. A controller controls the switching amplifier to selectively operate in at least a first or second modes based on the input signal, wherein in each mode, output nodes are modulated between switching voltages with a controlled duty-cycle and at least one of the switching voltages is different in the different modes. In steady-state operation in the first mode a common-mode voltage applied to the first and second output nodes has a first value and in steady-state operation in the second mode a common-mode voltage applied to the first and second output nodes has a second value, different to the first value; wherein at least one of first values and the second values is not equal to a voltage which is halfway between the switching voltages used in that mode.

### FIELD OF DISCLOSURE

The field of representative embodiments of this disclosure relates to methods, apparatus and/or implementations concerning or relating to switching amplifiers, i.e. to switched-mode drivers such as class-D amplifiers or the like.

### BACKGROUND

Switching amplifiers, also called switched-mode amplifiers, such as class-D amplifiers and the like, are used in a variety of applications for driving load transducers, such as audio output transducers or the like, and can have advantages in terms of power efficiency compared to linear amplifiers. Class-D amplifiers typically comprise an output stage for modulating at least one output node between defined switching voltages with a duty-cycle such that the average voltage, over the course of one or more switching cycles, has the desired level.

Class-D amplifiers may often be implemented to drive the load transducer in a bridge-tied-load (BTL) configuration, and thus the load may be connected between first and second output nodes, each of which is modulated between defined switching voltages to generate the desired differential driving voltage across the load (on average across the switching cycle).

In some examples, each of the first and second output nodes may be modulated between two defined switching voltages that do not substantially vary in use, e.g. between a high-side voltage VH and a low-side voltage VL defining an input voltage Vin=VH−VL. In this case, by appropriate control of the duty cycle of modulation of on both sides of the load, a differential drive signal in the range of +Vin to −Vin may be developed across the load. In some applications, however, e.g. for relatively high-power applications, the magnitude of the input voltage Vin, i.e. the voltage difference between the high-side voltage and the low-side voltage, may need to be relatively high to be able to achieve the desired output range for the differential drive signal. Continually switching each output node between two switching voltages with a relatively large voltage difference between them can lead to issues with EMI (electromagnetic interference) and also power losses.

In at least some applications, in particular for relatively high-power applications and/or in applications where there may be a relatively long output path between the output stage and the load, such as automotive or home theatre applications, there may be an output filter for filtering applying filtering to the output of the amplifier so as to provide the drive signal for the load. Such an output filter may typically be implemented by an inductance-capacitance (LC) filter, with a series inductance in the output path and a shunt capacitance to a defined voltage, such as ground. Switching the output nodes between switching voltages with a relatively large voltage difference between them can lead to a relatively large ripple current in the inductor and inductor core losses may be significant.

To mitigate this problem, multi-level switching amplifiers have been proposed, in which the switching voltages used for modulating the output nodes may be dynamically varied in use based on the amplitude of differential output signal. For instance, as well the high-side and low-side voltages VH and VL there may be at least one intermediate voltage VM which is voltage between the high-side voltage VH and the low-side voltage VL. For example, the high-side voltage VH could be a supply voltage VDD, the low-side voltage could be ground and the intermediate voltage VM could be between the high-side and low-side voltages, say VDD/2 for example, although other values for the intermediate voltage could be used. In this case, when the required differential drive signal has a relatively high amplitude, e.g. with an amplitude from about VDD/2 to VDD, the switching amplifier may modulate the output nodes between the high-side and low-side voltages, e.g. between VDD and ground. However, if the differential drive signal is in a low amplitude range, e.g. with an amplitude lower than VDD/2, the relevant differential drive signal can be generated by modulating each of the output nodes between the intermediate voltage and the low-side voltage, i.e. between VDD/2 and ground. This reduces the voltage difference of the modulation of the output nodes, with consequent advantages for EMI and power loss.

Such a multi-level switching driver can thus be seen as operating in different modes, where the switching voltages used for modulating the output nodes are different in the different modes. Dynamically varying the mode of operation in use can provide benefits in reduced EMI and/or power consumption. However, in at least some applications, changing the mode of operation can lead to unwanted current/voltage transients and/or could result in artefacts in the output signal.

### SUMMARY

Embodiments of the present disclosure relate to methods and apparatus for multi-level switching amplifiers that at least mitigate at least some of above-mentioned issues.

According to an aspect of the disclosure there is provided a controller for controlling a switching amplifier to modulate voltages at first and second output nodes so as to drive a load connected between said first and second output nodes with a differential drive signal based on an input signal. The controller is configured to control the switching amplifier to selectively operate in at least a first mode or a second mode, wherein in each of the first and second modes, the first and second output nodes are modulated between switching voltages with a controlled duty-cycle and at least one of the switching voltages is different in the first mode compared to the second mode. The controller is configured to control the mode of operation based on the input signal such that the switching amplifier can dynamically swap between the first and second modes. The controller is configured such that, in steady-state operation in the first mode a common-mode voltage applied to the first and second output nodes has a first value and in steady-state operation in the second mode a common-mode voltage applied to the first and second output nodes has a second value, different to the first value; wherein at least one of first values and the second values is not equal to a voltage which is halfway between the switching voltages used in that mode.

In the first mode, the first and second output nodes may be modulated between first and second switching voltages; and in the second mode the first and second output nodes may be selectively modulated between the first switching voltage and a third switching voltage, wherein the third switching voltage is an intermediate voltage between the first and second switching voltages. In some implementations, the controller may be configured such that the second value is closer to the first value than a value which is halfway between the first and third switching voltages. In some implementations, the controller may be configured such that the first value is closer to the second value than a value which is halfway between the first and third switching voltages. In some implementations, the first switching voltage may be ground, the second switching voltage may be a high-side voltage VH and the third switching voltage maybe an intermediate voltage VM and the controller may be configured such that the first value of the common-mode voltage applied to the first and second output nodes in steady-state operation in the first mode of operation is equal to VH/2 and the second value of the common-mode voltage applied to the first and second output nodes in steady-state operation in the second mode of operation is greater than VM/2.

In some implementations, the controller may be further configured, during a transitional period of operation in the first mode, to controllably vary the common-mode voltage applied to the first and second output nodes away from the first value. During the transitional period of operation in the first mode the controller may be configured to ramp the common-mode voltage applied to the first and second output nodes from the first value to the second value or vice versa.

Aspects also relate to a switching amplifier circuit comprising the controller of any of the embodiments described herein and an output stage. The output stage may comprise a respective bridge arrangement for each of the first and second output nodes. The bridge arrangement may comprise a first switch for connecting the respective first or second output node to the first switching voltage, a second switch for connecting the respective first or second output node to the second switching voltage and a third switch for connecting the respective first or second output node to the third switching voltage.

In another aspect, there is provided a controller for controlling a switching amplifier to modulate voltages at first and second output nodes so as to drive a load connected between said first and second output nodes with a differential drive signal based on an input signal, the controller being selectively operable in at least first and second modes. The first mode comprises modulating the first and second output nodes between switching voltages defining a first voltage range, and the second mode comprises modulating the first and second output nodes between switching voltages defining a second voltage range, different from the first voltage range. In at least one of the modes, the controller is configured to control said modulation of the first and second output nodes such that a common mode voltage at the first and second output nodes is spaced from the midpoint of the voltage range for that mode.

In a further aspect, there is provided a controller for controlling a switching amplifier to modulate voltages at first and second output nodes so as to drive a load connected between said first and second output nodes with a differential drive signal based on an input signal. The controller is configured to control the switching amplifier to selectively operate in at least a first mode or a second mode based on the input signal such that the switching amplifier can dynamically swap between the first and second modes; wherein in the first mode, the first and second output nodes of the switching amplifier are selectively connected to first and second switching voltages with a controlled duty-cycle and in the second mode the first and second output nodes of the switching amplifier are selectively connected to said first switching voltage and a third switching voltage with a controlled duty-cycle, wherein the third switching voltage is an intermediate voltage between the first and second switching voltages; wherein the controller is configured to selectively increase an output resistance of the switching amplifier during a damping period which, at least partly, follows a change in mode.

In a further aspect, there is provided a controller for controlling an output stage of switching amplifier to modulate voltages at first and second output nodes so as to drive a load connected between said first and second output nodes with a differential drive signal based on an input signal, wherein: the controller is configured to control the switching amplifier to selectively operate in at least a first mode or a second mode based on the input signal such that the switching amplifier can dynamically swap between the first and second modes; and in the first mode, each of the first and second output nodes is modulated between first and second switching voltages with a controlled duty-cycle by controlling respective first and second switches; in the second mode, each the first and second output nodes is modulated between said first switching voltage and a third switching voltage with a controlled duty-cycle by controlling said first switch and a third switch respectively, where the third switch voltage is an intermediate voltage between the first and second switching voltages; wherein the second switch has a lower on-resistance that the third switch and wherein the first switch is operable in first and second on-states, where the first on-state has a lower on-resistance than the second on state; and the controller is configured to operate the first switch in the first on-state during operation in the first mode and to operate the first switch in the second on-state in the second mode.

In a further aspect, there is provided a controller for controlling a switching amplifier to modulate voltages at first and second output nodes so as to drive a load connected between said first and second output nodes with a differential drive signal based on an input signal, wherein: the controller is configured to control the switching amplifier to selectively operate in at least a first mode or a second mode, wherein in each of the first and second modes, the first and second output nodes are modulated between switching voltages with a controlled duty-cycle and at least one of the switching voltages is different in the first and second modes; the controller is configured to control the mode based on the amplitude of the input signal such that the switching amplifier can dynamically change between the first and second modes; the controller is configured such that in operation in the first mode a common-mode voltage applied to the first and second output nodes has a first steady-state value and in operation in the second mode a common-mode voltage applied to the first and second output nodes has a second steady-state value, different to the first steady-state value; and for a change in mode between the first and second modes, the controller is configured to operate in a transitional period before and/or after the change in mode wherein, during the transitional period, the common-mode voltage applied to the first and second output nodes is ramped over time so that any step change in common-mode voltage on the change in mode is less than the difference between the first and second steady-state values.

In a further aspect, there is provided a controller for controlling a switching amplifier to modulate voltages at first and second output nodes so as to drive a load connected between said first and second output nodes with a differential drive signal based on an input signal, wherein: the controller is configured to control the switching amplifier to operate in at least a first mode of operation in which the first and second output nodes of the switching amplifier are selectively modulated between first and second switching voltages with respective controlled duty-cycles; and the controller is configured to control said duty-cycle so as to controllably vary a common-mode voltage applied to the first and second output nodes in operation in the first mode; wherein the controller comprises a first control loop for controlling the common-mode voltage and a second control loop for controlling the differential drive signal.

In a further aspect, there is provided a switching amplifier for driving a load comprising: first and second amplifier signal paths for modulating respective first and second output nodes between switching voltages so as to generate a differential drive signal across a load connected between the first and second output nodes by respective first and second output paths; wherein the switching amplifier is operable such that a common-mode voltage applied to the first and second output nodes may be controllably varied in use; wherein the switching amplifier further comprises at least one compensator configured to apply compensation to at least one of the first and second amplifier signal paths to compensate for any mismatch in transfer function of the first and second output paths.

It should be noted that, unless expressly indicated to the contrary herein or otherwise clearly incompatible, then any feature described herein may be implemented in combination with any one or more other described features.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 illustrates one example of a multilevel switching amplifier for driving a load in BTL configuration;

FIG. 2 illustrates example switching waveforms in different modes of operation of the switching amplifier of FIG. 1;

FIG. 3 illustrates voltage waveforms illustrating the issue of ringing following a change in common-mode voltage;

FIG. 4 illustrates the equivalent common-mode circuit for the switching amplifier of FIG. 1;

FIGS. 5a and 5b illustrate two examples of switching arrangement for applying a variable resistance;

FIG. 5c illustrates one example of T-bridge using variable resistance switches;

FIG. 6 illustrates voltage waveforms illustrating the extend of any ringing with and without damping applied;

FIG. 7 illustrates a switching amplifier with separate integrated circuits providing the output bridge;

FIG. 8 illustrates waveforms showing a gradual change in common-mode voltage;

FIG. 9 illustrates one example of a signal path for a switching amplifier with look-ahead for changes in signal amplitude;

FIG. 10 illustrates voltage waveforms illustrating the extend of any ringing with and without a gradual change of common-mode voltage during a transitional period;

FIG. 11 illustrates another example of a multilevel switching amplifier for driving a load in BTL configuration;

FIG. 12 illustrates one example of a modulator arrangement for driving a switching amplifier such as illustrated in FIG. 1 or FIG. 11;

FIG. 13 illustrates another example of a modulator arrangement for driving a switching amplifier such as illustrated in FIG. 1 or FIG. 11;

FIG. 14 illustrates different transfer functions on different sides of the load and a resultant common-mode to differential transfer function due to mismatch in the filter arrangements on either side of the load;

FIG. 15 illustrates on example of system identification of the transfer function for the filter arrangement on one side of the load; and

FIG. 16 illustrates one example of applying compensation for mismatch in the filter arrangements on either side of the load.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

Embodiments of the disclosure relate to multi-level switching amplifiers, i.e. switching amplifiers in which amplifier output nodes may be modulated between switching voltages to generate a desired output voltage, on average over the course of one or switching cycles, and where the switching voltages used for modulating the output nodes may be dynamically varied in use.

FIG. 1 illustrates one example of a multi-level switching amplifier 100 for driving a load 101. The switching amplifier 100 is configured to drive the load 101, which, in this example, is an audio transducer (but which in other examples could be other types of transducer), in a bridge-tied-load (BTL) configuration and thus, in use, the load 101 is connected between first and second output nodes 102-1 and 102-2 of an output stage 103 of the switching amplifier 100.

In at least some implementations, there may be an output filter arrangement 104 for applying filtering in the output path from each output node 102-1 and 102-2 to the load. As will be understood by one skilled in the art, for some applications, some filtering in the output path may be important, for instance for relatively high-power applications, e.g. for driving an output power of 10 W or greater, and/or where the output path between the output nodes 102-1 and 102-2 of the switching amplifier 100 and the load 101 may be relatively long, e.g. of the order of tens of centimetres or greater. For example, audio systems in automotive applications and home theatre and the like may typically be required to output relatively high output powers and may have output paths of the order of tens of centimetres to meters between the switching driver and the loudspeaker being driven and, in such applications, filtering of the output path may be important. Typically, the output filter may comprise an LC (inductance-capacitance) filter arrangement which is separate to the load 101. FIG. 1 illustrates one example of a basic filter arrangement 104 with a series inductance Lfil in the output path and capacitance Cfil between the output path and a defined reference voltage, such as ground, on each side of the load. Other LC filter arrangements may be implemented, however, as would be understood be one skilled in the art. Where the output stage 103 of the switching amplifier 100 is implemented as an integrated circuit, the filter arrangement 104 may be implemented, at least partly by external components, i.e. components which are off chip and not part of the integrated circuit.

The output stage 103 is operable such that the first and second output nodes 102-1 and 102-2 can be selectively connected to a high-side voltage VH, e.g. a supply voltage, and to a low-side voltage, which in this example is ground. In the example of FIG. 1 these connections are provided by switches SH and SL respectively. In addition, each of the first and second output nodes 102-1 and 102-2 can be selectively connected to an intermediate voltage VM, where the intermediate voltage is a voltage at a level which is between the high-side voltage and low-side voltage. In the example of FIG. 1 the connection between the relevant output node 102-1 or 102-2 and the intermediate voltage VM is via a respective switch SM.

This switching arrangement, where an output node can be selectively connected to three different voltages by respective switching paths is often referred to as a T-bridge or a Y-bridge and shall be referred to herein as a T-bridge, although it should be understood that this is just a convenient label and nothing should be implied about the physical layout of the switching paths by use of the term T-bridge. The output stage 103 of the example of FIG. 1 thus comprises first and second T-bridges for modulating the first and second output nodes 102-1 and 102-2 respectively.

In use, a switch controller 105 controls the switching of the T-bridges of the output stage 103 based on an input signal Sin, so as to modulate the voltages of the output nodes in a switching cycle that generates the desired differential voltage across the load, on average over the course of the switching cycle. In the example of FIG. 1, the switch controller 105 may be operable in two different modes. In a first mode, which may be seen as a high-level mode, the switch controller 105 modulates each of the output nodes 102-1 and 102-2 between the high-side voltage VH and the low-side voltage, i.e. ground in this example. In a second mode, which may be seen as a low-level mode, the switch controller 105 modulates each of the output nodes 102-1 and 102-2 between the intermediate voltage VM and the low-side voltage, i.e. ground in this example. The switching controller 105 may selectively operate in the first mode or the second mode depending on the amplitude of the desired differential drive voltage. For instance, for a differential drive signals with an amplitude greater than the intermediate voltage VM (or greater than |(VM−VL)| if VL is not ground), the switching amplifier 100 may operate in the first, high-level, mode, but for amplitudes lower than a defined threshold, which is equal to or lower than VM (or |(VM−VL)|), the switching amplifier 100 may operate in the second, low-level, mode. The mode of operation may be determined by comparing the amplitude or peak value of the input signal Sin, e.g. an envelope value derived from the input signal, with at least one threshold, possibly with some hysteresis applied to prevent frequency changes in mode for signal amplitudes near the threshold. Operating in the second mode for an input signal Sin with an amplitude below the defined threshold can reduce EMI and power consumption compared to operating in the first mode, but the ability to operate in the first mode for amplitudes above the defined threshold allows the switching amplifier to deliver a desired output range for the differential drive signal.

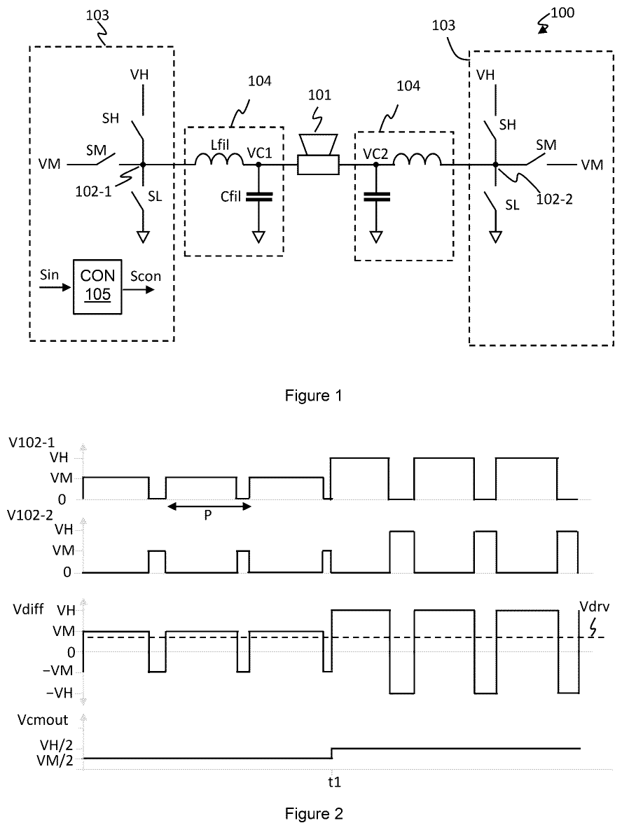

FIG. 2 illustrates example idealised switching voltage waveforms for the switching amplifier 100 of FIG. 1. FIG. 2 illustrate how the voltages V102-1 and V102-2 at the output nodes 102-1 and 102-1 respectively are modulated over time in a number of switching cycles having a period P. FIG. 2 also illustrates the resulting instantaneous differential voltage Vdiff between the output nodes (where a positive differential voltage corresponds to the voltage at output node 102-1 being more positive than the voltage at output node 102-1) over the switching cycles and also an indication of the resulting drive voltage Vdrv, i.e. the average differential voltage between the output nodes over the course of the switching cycle.

FIG. 2 illustrates that initially the switching amplifier is operating in the second mode in which each of the output nodes 102-1 and 102-2 is modulated between the intermediate voltage VM and ground. The switching amplifier 100 is operated in this second mode when the amplitude of the differential drive signal is lower than a first threshold, which may be equal to or lower than the intermediate voltage VM.

FIG. 2 illustrates that the switching amplifier 100 is operated with AD modulation and thus the voltages at the output nodes 102-1 and 102-2 are modulated in antiphase such that the instantaneous differential voltage Vdiff is modulated between +VM and −VM.

In the example of FIG. 2, at a time t1, the switching amplifier changes to the first mode in which the output nodes 102-1 and 102-2 are modulated between the high-side voltage VH and ground, with an appropriate change in duty-cycle to maintain the correct average differential output voltage. The switching amplifier 100 may be configured to change the mode of operation from the second mode to the first mode when it is determined that the amplitude of the differential drive signal will exceed the threshold, i.e. the peak signal excursion will reach close to or exceed a limit for the drive signal to be correctly generated in the second mode of operation.

It can thus be seen that the switching amplifier 100 can swap between these two modes of operation with a change in switching voltages used for modulation and a corresponding change in duty-cycle to maintain the same average differential output voltage. Changing the switching voltages used for modulation in this way does, however, result in a change in the common-mode voltage Vcmout applied to the output nodes 102-1 and 102-2. When operating in the second mode the common-mode voltage Vcmout applied to the output nodes is, for the AD modulation described, equal to half the intermediate voltage, i.e. VM/2, whereas when operating in the first mode the common-mode voltage Vcmout applied to the output nodes is half the high-side voltage, i.e. VH2. This step change in the common-mode voltage Vcmout applied to the output nodes 102-1 and 102-2 can lead to unwanted transients in the output path. In particular, this sudden change or jump in common-mode voltage applied to Vcmout applied to the output nodes can lead to ringing in the output path, in particular within the filter arrangement 104 in the output path. Sudden changes in the level of the common-mode voltage also have significant high frequency content. As the output filter arrangements 104 on either side of the load 101 typically may exhibit some mismatch, particularly at high frequencies (in this case, approximately 1 k-20 kHz), this can lead to distortion as the common-mode component may be converted to differential mode. This limits amplifier performance.

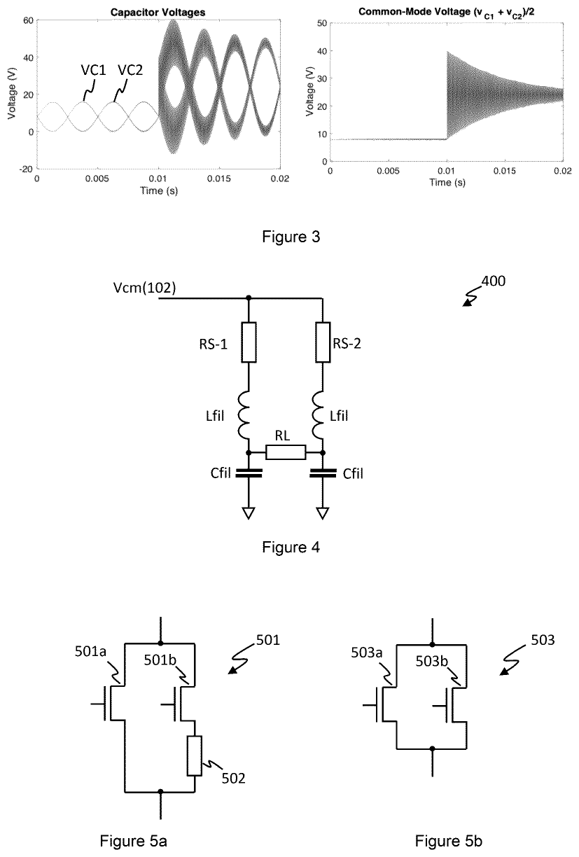

FIG. 3 illustrates this issue. A switching amplifier 100 such as illustrated in FIG. 1 was implemented with, in this example, a high-side voltage VH of 48V and an intermediate voltage VM of 16V. The left-hand plot of FIG. 3 illustrates the voltages VC1 and VC2 on the capacitors Cfil of the filter arrangement 104 and the right-hand plot shows the common-mode Vcmfil of these two voltages, i.e. Vcmfil=(VC1+VC2)/2.

In this example, the switching amplifier was initially driven with a sinusoidal input signal with an amplitude corresponding to a drive signal amplitude of 16V and was operated in the second mode of operation. It can be seen that during this period the voltages VC1 and VC2 the capacitors Cfil of the filter arrangement 104 follow the differential drive signal and the common-mode voltage Vcmfil of these capacitor voltages is substantially constant (at 8V in this example).

At a certain point in time, illustrated as 0.01 s in these plots, the amplitude of the input signal increased to an amplitude corresponding to a drive signal amplitude of 48V and the switching amplifier 100 changed to operating in the first mode of operation. This results in a change to the common-mode voltage Vcmout applied to the output nodes. It can be seen that directly after the change in the mode, the capacitor voltages VC1 and VC2 exhibit a large oscillation about the desired differential drive signal and the common-mode voltage Vcmfil of the capacitor voltages exhibits a large oscillation about the new common-mode level of 24V.

This occurs because of ringing in the common-mode circuit formed by the switching amplifier 100, together with the filter arrangement 104 and load 101. The common-mode circuit is substantially undamped and thus the response to the common-mode circuit to the step change in common-mode of the output signal results in significant ringing or oscillation, which can persist for a relatively long-time, e.g. of the order of tens of milliseconds as illustrated in FIG. 3. This effect is more pronounced at higher power levels, where the voltages are larger and the switch resistances (i.e. the main component damping the circuit) are lower. This ringing can lead to an increase in EMI and/or increased power losses, e.g. in inductor core losses, and thus is undesirable.

A further issue that can arise on a change of mode in this way, is that, as noted above, any mismatch in the output stage 103 or filter arrangement 104 on either side of the load, e.g. a mismatch in switch resistance or inductance value, can, on a sudden change in common-mode component, result in common-mode to differential conversion and thus lead to an unwanted artefact in the differential drive signal.

One way to avoid this issue would be to avoid a change in common-mode voltage on a change in mode, which could be achieved by changing both the switching voltages used for modulating the output nodes in the different modes (instead of changing just one of the voltages used). For instance, a switching amplifier could be implemented with a first mode in which the output nodes 102-1 and 102-2 are modulated between the high-side voltage VH and the low-side voltage VL and a second mode in which the output nodes 102-1 and 102-2 are modulated between two different intermediate voltages VM1 and VM2. If the intermediate voltages VM1 and VM2 were configured such that (VM1+VM2)/2=(VH+VL)/2, then swapping between the two modes could avoid any significant change in the common-mode voltage. However, this does require a second intermediate voltage to be available, which would typically require additional circuitry for generating the second intermediate voltage, which would add to the circuit area and cost and also the power consumption in use, and, in any case, there would need to be additional switching connections for connecting the second intermediate voltage to the output nodes which again would increase the circuit area. Additionally, in implementations where four or more different voltages are available for use as switching voltage, i.e. there may be at least two different intermediate voltages, it may be desired to operate in different modes of operation that result in different values of common-mode voltage in continuous operation in a given mode.

Embodiments of the present disclosure thus relate to switching amplifiers which are operable in different modes in which the switching voltages used for modulating the output nodes differ in the different modes and where a change in mode can result in a change in the common-mode voltage of the output signal and to methods and apparatus for operation of such switching amplifiers. Embodiments of the present disclosure mitigate for at least some adverse effects that can arise on a change in common-mode voltage of the output of the switching amplifier.

Embodiments of the present disclosure may mitigate for the effects of a change in common-mode voltage in one or more of a number of different ways.

### Dynamic Damping Control

In some applications the effects of a change in the common-mode of the output voltage may be suppressed by dynamically applying damping on a mode transition, e.g. applying damping for a period of time following a mode transition when ringing might otherwise be expected.

As noted above, the common-mode circuit for the switching amplifier 100 together with the filter arrangement 103 and load 101 may, in at least some implementations, not have much significant damping. FIG. 4 illustrates the equivalent common mode circuit 400 for the switching amplifier arrangement illustrated in FIG. 1, where RS-1 and RS-2 represent the output resistance of the output stage 103 on either side of the load and RL represents the load resistance of the load 101. The impact of the load resistance RL on the common-mode response is generally minimal and thus can be ignored.

It will be understood by one skilled in the art that in the circuit 400 illustrated in the FIG. 4, the common-mode response is principally damped by the resistances RS-1 and RS-2 of the output stage 103, which are largely governed by the on-resistances of the relevant ones of the switches SH, SM and SL of the T-bridge being switched in the relevant mode. Typically, these switch on-resistances are relatively low, so as to avoid unwanted resistive losses during operation, and this means that the common-mode response may be largely undamped.

Adding some permanent series resistance to provide damping would be undesirable in terms of increasing losses and thermal dissipation, when operating continuously in a given mode. In embodiments of the present disclosure, some additional damping may be dynamically applied during a damping period following (and possibly for a short period before) a change in mode, and the additional damping may then be disabled or removed at the end of the damping period for continued operation in the new mode.

There are various ways some damping could be selectively applied for a damping period. For example, the output impedance of the switching amplifier 100 may be temporarily increased.

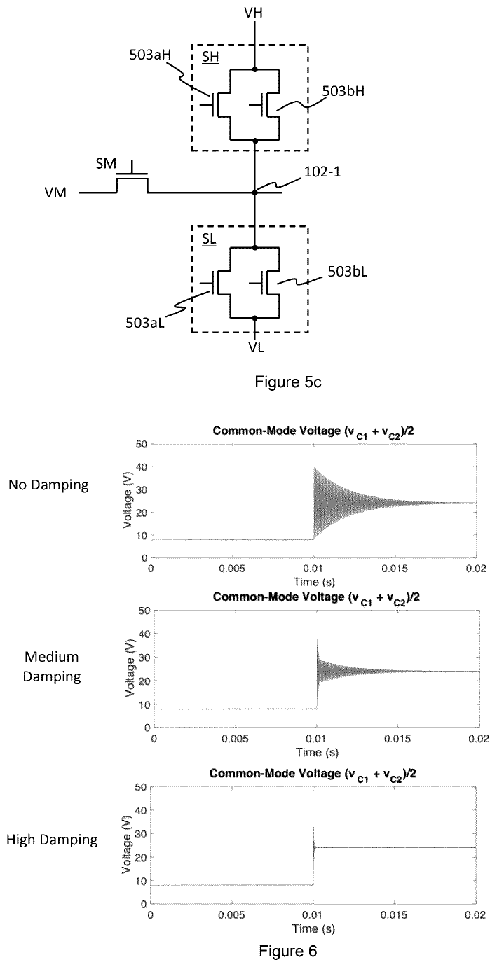

FIGS. 5a and 5b illustrates two examples of switching arrangements that could be used to increase the output impedance.

FIG. 5a illustrates a first switch arrangement 501 that can be used to selectively connect a series resistance 502 into the output path of the T-bridge to selectively increase the damping applied when desired. The first switch arrangement 501 comprises a first switch 501a in a first circuit branch and a second switch 501b connected in a second circuit branch with the series resistance 502. The first and second circuit branches are connected in parallel so that first switch arrangement 501 can be operated with the first switch 501a on and the second switch 501b off so as to provide a low-resistance conductive path via the first circuit branch and can be operated with the second switch 501b on and the first switch 501a off so as to provide a high-resistance conductive path via the second circuit branch.

At least one switch arrangement 501 could be arranged as part of the T-bridge on each side of the load and could, for example, be connected between the relevant switches of the T-bridge and the relevant output node 102-1 or 102-2. In general, to provide an increased output resistance, the additional series resistance should be connected in series between the output node and the relevant voltage supply for the relevant mode of operation, i.e. between the high-side voltage VH and the output node when operating in the first mode, and between the intermediate voltage VM and the output node when operating in the second mode. The switch arrangement 501 could, for instance, be connected in a common part of an output path for both switches, i.e. the switches SH and SM could each connect to a first common node, which is connected to the relevant output node 102-1 or 102-2 via the switch arrangement 501. At least for implementations where the low-side voltage is ground, it may not be necessary for the series resistance to be connected between the low-side voltage VL and the load for the relevant part of the switching cycle, and thus low-side switch SL could be connected to the output node via a path that bypass the switch arrangement 501, but in some arrangements it may be simpler to also have the low-side switch connect to the first common node.

In continuous or steady-state operation in a given mode of operation, the first switch 501a may be on to enable the low-resistance path, with the second switch 501b off. However, during the damping period in which increased damping is to be applied, the second switch 501b may be turned on and the first switch 501a may be turned off, so that the high-resistance path via the series resistance 502 is enabled. In this way the output resistance of the output stage can be selectively increased to provide increased damping during the damping period.

Alternatively, to avoid additional switches in the output path, the first switch arrangement 501 could be used to implement each of the switches SH and SM as switches with a variable on-resistance, e.g. one switch arrangement 501 may be used as the high-side switch SH and another switch arrangement 501 used as the switch SM. Optionally, the low-side switch SL could also be implemented by such a switch arrangement, which may be advantageous in balancing the switch resistance of the low-side switch with the resistance of the relevant one of the switches SH or SM dependent on the mode of operation, as will be discussed in more detail below. The first switch arrangement 501 may be controlled to be in an off-state, i.e. non-conducting, by controlling both the first and second switches 501a and 501b to be off. The switch arrangement 501 may also be controlled to be in either of two different on-states, i.e. states allowing conduction, by turning either the first switch 501a on, to provide a low-resistance on-state, or by turning the second switch 501b on, to provide a high-resistance on-state.

FIG. 5b illustrates a second switch arrangement 503 that could be used to implement the switches SH and SM, and optionally switch SL, to provide switches with a variable on-resistance.

The second switch arrangement 503 comprises first and second switch elements 503a and 503b in parallel and which may, for example, be implemented as part of a split-switch arrangement as would be understood by one skilled in the art. The second switch arrangement 503 may also be controlled to be in an off-state and also at least as a low-resistance on-state or a high-resistance on-state. In some examples, to provide the low-resistance on-state, the whole of the switch arrangement 503 may be turned on, i.e. both the first and second switch elements 503a and 503b are turned on and conducting, and the on-resistance of the second switch arrangement 503 is governed by the on-resistances of the first and second switch elements 503a and 503b in parallel. In the high-resistance on-state, only a proportion of switch arrangement is turned on, i.e. only one of the first and second switch elements 503a and 503b is turned on and conducting, and the other of the first and second switch elements 503a and 503b is off and non-conducting. In this high-resistance on-state, the on-resistance of the switch arrangement is governed by the on-resistance of whichever of the first and second switch elements 503a and 503b is turned on. The first and second switch elements 503a and 503b may be arranged to provide different on-resistances to one another, for instance if the first and second switch elements 503a and 503b are implemented by MOSFETs for example, at least one dimension of the channel, e.g. channel width, of the first and second switch elements 503a and 503b may be different. In this way a desired on-resistance for the high-resistance on state can be achieved, whilst also allowing a desired low on-resistance for the whole switch arrangement 503 in the low-resistance on state.

It will be noted that the first and second switch elements 503a and 503b may each be fully turned on or off as required, i.e. operated with a minimum on-resistance for that switch element when on, and the resistance is controlled by varying the proportion of the switch arrangement 503 which is turned on. This is not the same as operating the switching element 503a or 503b in the linear regime so as to controllably vary the effective resistance of the switching element 503a and 503b itself.

First or second switch arrangements 501 or 503 such as illustrated in FIGS. 5a and 5b could be used to implement the switches SH and SM of each of the T-bridges of the output stage 103 as illustrated in FIG. 1, to allow the relevant switch to be selectively operated in the low-resistance on-state or the high-resistance on-state, during the relevant part of the switching cycle when it is turned on. During continuous or steady-state operation of the switching amplifier 100 in a given mode, the relevant switch may be operated in the low-resistance on-state so as to reduce switching losses. However, on a change of mode, the relevant switch may be operated in the high-resistance on-state during a damping period, so as to provide an increased output resistance for the switch amplifier 100 and thus provide an increase in damping for the common-mode circuit.

Thus, for example, consider that the switching amplifier 100 is operating in the second mode with the first and second output nodes 102-1 and 102-2 being modulated between the intermediate voltage VM and the low-side voltage, e.g. ground. In this mode of operation, it is the switches SM and SL that are being duty-cycled in a complementary manner for each of the T-bridges and switch SM can be turned on in the low-resistance on state for the relevant part of the switching cycle. On a change in mode to the first mode of operation, it is switches SH and SL of each T-bridge that are duty-cycled in a complementary manner (and switch SM is maintained in an off-state). On the change in mode, and for a period of time thereafter (corresponding to the damping period), the SH switch can be turned on, when required in the switching cycle, in the high-resistance on-state so as increase the output resistance of the switching amplifier 100 and provide damping of any ringing in response to the change in common-mode voltage. The damping period in which the switches SH of the T-bridges are operated in the high-resistance on-state may be defined based on the time-constant of the common-mode circuit so that the damping is applied during a period over which ringing would be expected. After the damping period, the switches SH of the T-bridges may be operated so as to be turned on, when required in the switching cycle, in the low-resistance on-state for continued operation in the first mode.

For the opposite change of mode, i.e. a change in mode from the first mode to the second mode, it would the switches SM of the T-bridges that would be operated in the high-resistance on-state during the damping period following the change to operation in the second mode.

It will be understand that implementing the high-side switch SH as a switch with a variable on-resistance in this way allows for selective damping to be applied in the first mode of operation and implementing the intermediate switch SM as a switch with a variable on-resistance allows for selective damping to be applied in the second mode of operation, but if it were desired to apply selective damping in only one mode of operation, it would be sufficient for just the relevant one of the SH or SM switches to be implemented as a switch with a variable on-resistance.

For example, FIG. 5c illustrates an example of a T-bridge in which the high-side switch SH is implemented as a switch with a variable on-resistance, but the switch SM is not.

It is generally preferable for the high-side switch SH to be operable with a relatively low on-resistance during continuous operation in the first, high-level, mode of operation as a relatively high load current may be drawn through the high-side switch SM in operation in this mode and the on-resistance can be important in terms of resistive losses. In the example of FIG. 5c, the high-side switch SH is therefore be implemented to have a variable resistance and, in this example, comprises a switch arrangement such as described with reference to FIG. 5b, with first and second switching elements 503aH and 503bH. The switch arrangement may be configured so as to be operable in a low-resistance on-state, e.g. with both switch elements 503aH and 503bH turned on, to provide a low on-resistance in continuous operation in the first mode, but to be operable in a high-resistance on-state, e.g. with just one of the switch elements 503aH or 503bH turned on, to apply damping during a damping period following transition to operation in the first mode.

However, for the switch SM, which is only used in second, low-level, mode of operation, the load current in use in this mode may be significantly lower than in the first mode, and resistive losses may be less of a concern. Instead, switching losses associated with turning the switch SM on and off may be more of a concern and it may, therefore, be advantageous to implement switch SM using a switch which result in lower switching losses during continuous operation in the second mode. Such a switch may, for example, be implemented as by a MOSFET switch which is smaller than the switch arrangement used for the high-side switch SH (in the low on-resistance state) and which thus has a smaller gate capacitance but higher on-resistance. In some implementations the on-resistance for the switch SM which is acceptable for continuous use in operation in the second mode may be sufficiently high to provide sufficient damping of any ringing induced by a change in common-mode voltage on a transition to the second mode of operation. In which case, it may not be necessary to implement the switch SM as a switch with a variable resistance as the fixed nominal resistance of the switch SM used in continuous operation in the second mode may provide sufficient damping without the needed to use a higher resistance during a damping period. Thus, as illustrated in FIG. 5c, the switch SM may be implemented by a single switching element to provide a nominally fixed on-resistance (for a given set of operating conditions such as temperature etc.).

FIG. 5c also illustrates that, advantageously, the low-side switch SL is implemented as a switch with a variable resistance and, in this example, is also implemented by a switch arrangement such as illustrated in FIG. 5b with switch elements 503aL and 503bL in parallel. The low-side switch SL may be configured to be operable in with a low-resistance on-state, e.g. with both switch elements 503aL and 503bL turned on, in which the on-resistance may be substantially matched to the on-resistance of the high-side switch SH in its low-resistance on-state. This can allow the on-resistance of the low-side switch SL to be matched to the on-resistance of the high-side switch SH when in continuous operation in the first mode, which means that these switches present a balanced impedance, which can reduce distortion compared to operation with switches having different impedances.

However, when operating in the second mode (whether immediately following a mode transition or in continuous operation), the low-side switch SL may be operated in a high-resistance on-state, e.g. by turning on only one of the switch elements 503aL or 503bL. Turning on only part of the switch arrangement of the low-side switch SL will result in a higher on-resistance, but will reduce switching losses compared to turning on all of the switch arrangement. Advantageously the on-resistance of the low-side switch SL in the high-resistance on-state may be matched to the on-resistance of the switch SM, so as to provide balanced resistances when operating continuously in the second mode.

For the example of FIG. 5c, on a transition from the second, low-level, mode to the first, high-power mode, each of the switches SL and SM will be operating with a relatively high on-resistance in continuous operation in the second mode (as the switch SM inherently has a relatively high on-resistance and the switch SL is operated in its high-resistance on-state) and thus there may be no need for any additional resistance to be applied for additional damping prior to the mode transition. On transition to the first mode, the high-side and low-side switches may be initially operated in their high-resistance on-state during a damping period and then swap to operation in the low-resistance on-state at the end of the damping period for continued operation in the first mode. On the reverse transition, from the first mode to the second mode, the high-side and low-side switches SH and SL may each initially be operating in the low-resistance on-state and, in some implementations, may swap to operation in the high-resistance on-state immediately before the change in mode to provide some initial damping. On the change in mode, the switches SM and SL will operate continuously with a relatively high on-resistance and the variable resistance switch SL will be operated continuously in its high-resistance on-state which can therefore provide damping of any ringing due to a change in the common-mode voltage applied.

It should be noted that the use of a switch for the high-side switch which can provide a relatively low on-resistance during continuous operation in the first, high-level mode of operation and a switch for the intermediate voltage switch which can be switched with lower switching losses than the high-side switch, for use in continuous operation in the second, low-power mode, together with a variable switch arrangement for the low-side switch which can be selectively operated to provide a low on-resistance in continuous operation in the first, high-level mode of operation and lower switching losses in the continuous operation in the second, low-level mode of operation represents a novel aspect of this disclosure. It will be noted that this benefit of reducing the switching losses of the switch SM and SL used in the second, low-level, mode of operation, whilst providing suitable low on-resistances for the switch SH and SL used in the first, high-level, mode of operation would apply even if neither of the switches SM or SH were implemented as variable switch resistance to provide damping, e.g. the switch SH illustrated in FIG. 5c could, in some implementations, be implemented by a single switch element which provides a relatively low on-resistance.

However, as discussed above, implementing one or both of the switches SH and SM as variable resistance switches can allow for damping to be selectively applied to mitigate the issues of ringing following a step-change in common-mode voltage.

FIG. 6 illustrates waveforms of the common-mode voltage Vcmfil of the capacitor voltages for a switching amplifier 100 such as illustrated in FIG. 1 following a change in mode with and without damping resistance applied. The parameters of operation were the same as discussed for FIG. 3, and the waveforms illustrate the voltages common-mode voltage Vcmfil following a change in mode from the second mode to the first mode. The top plot shows the common-mode voltage Vcmfil of the capacitor voltages without any additional damping being applied and illustrates significant ringing as discussed with reference to FIG. 3. The middle plot illustrates the common-mode voltage Vcmfil of the capacitor voltages where the output resistance of the switching amplifier 100 was increased to provide what will be referred to as a medium level of damping, which in this example provided an output resistance of the order of an ohm, for a damping period of following the change in mode. It can be seen that the amount of ringing is significantly decreased. The lower plot illustrates the common-mode voltage Vcmfil of the capacitor voltages where the output resistance of the switching amplifier 100 was increased to provide what will be referred to as a high level of damping, in this example to provide an output resistance of the order of several ohms for the same damping period. It can be seen that ringing of the common-mode voltage Vcmfil is substantially suppressed.

It will be understood that changing the output resistance of the switching amplifier 100 in this way will impact the overall transfer function of the switching amplifier and could result in some distortion in the output drive signal. However, the switching amplifier 100 may typically be implemented to operated in a closed-loop manner, where some feedback (not illustrated) from the output of the switching amplifier is fed back to the switch controller 105 to be taken into account in setting the relevant duty-cycles so as to minimize any error between the input signal and the output signal and in at least some implementations the feedback loop will be sufficient to maintain any distortion arising from the change in output resistance within acceptable limits. Additionally or alternatively the modulator control within the switching controller could be updated to take account in the expected change in transfer function.

A switch controller of the switching amplifier may thus be configured to control switching of the relevant switches SH, SM and SL of the T-bridges of the switching amplifier to implement the different modes of operation and to control the duty-cycle of the relevant switches to generate the desired output drive signal and, additionally, may control the relevant switch to operate in a high-resistance on state, and/or control connection of some additional series resistance into the output path, during a damping period following a change in mode.

Optionally, the high-resistance on-state may also be used for a short period of time immediately before the change in mode occurs, as in some implementations this can help with the damping response. For example, considering the change in mode from the second mode to the first mode, the switching amplifier 100 will, as discussed above be duty-cycling the switches SM and SL in operation in the second mode and the switches SM may be operated in the low-resistance on-state. For a short period before the change in mode, e.g. for a few switching cycles before the change in mode occurs, the switches SM may be operated in the high-resistance on-state. This does require some advance knowledge that the mode is going to be changed, i.e. some degree of look ahead for the change in mode, which could be provided by some propagation delay between determining that a change in mode is required and the implementation of the change in mode, as will be discussed in more detail below.

It will be understood that the mode of operation will be changed because it is determined that the amplitude of the output drive signal is changing to a level appropriate for the new mode of operation, e.g. is crossing a relevant threshold for operation in the relevant mode. For a change from the first, high-level, mode of operation to the second, low-level mode of operation, this will be because the amplitude of the output drive signal has decreased sufficient to allow operation in the second, low-level, mode. The damping period will thus be applied at a time when the output signal amplitude is low and the load current will, consequently, be expected to be relatively low throughout the damping period. For a change from the second, low-level, mode of operation to the first, high-level mode of operation, this will be because the amplitude of the output drive signal is increasing. In this case, the amplitude of the output drive signal could increase to a high level during the damping period following the change in mode. This could result in a relatively high load current being drawn, for example during any signal peaks, during the damping period when the output resistance of the switching amplifier is relatively high, which may lead to relatively high switching losses.

If there is some degree of look ahead of when the change in mode is required, then the mode change from the second, low-level, mode to the first, high-level mode, could be made ahead of when the increase in signal amplitude occurs. This could allow for at least part of the damping period to be implemented when the signal amplitude is still relatively low and thus the load current is expected to be relatively low, so as to reduce or avoid increased losses due to a high-load current being drawn when the output stage of the switching amplifier is operating in a high-resistance state. Advantageously the change in mode may be made so that the damping period ends, and the output stage of the switching amplifier 100 returns to low-resistance operation, just before any load current is drawn.

In some embodiments, at least some of the switches of the switching amplifier 100 may be implemented as part of a separate integrated circuit (IC) to that comprising the switch controller. This can allow each integrated circuit to be more optimised for its purpose and, in particular, can allow for different material systems to the be for the different integrated circuits. For instance, for high power applications it can be advantageous to implement at least some of the switches in a compound semiconductor material system such as a Gallium Nitride based IC, whereas it may be more convenient to implement the switch controller, and any other signal processing or amplifier control circuitry, in a conventional silicon-based IC. Using two different integrated circuits can allow each circuit to be optimized for its intended use in this way. In some examples, there may therefore be a first IC which implements the output bridge and a second IC for controlling the output bridge. However, to implement an output stage with a T-bridge for each side of the load, where the T-bridges comprise switch arrangements such as illustrated in FIG. 5 to provide a variable on-resistance for damping purposes would require a custom IC design for the first IC.

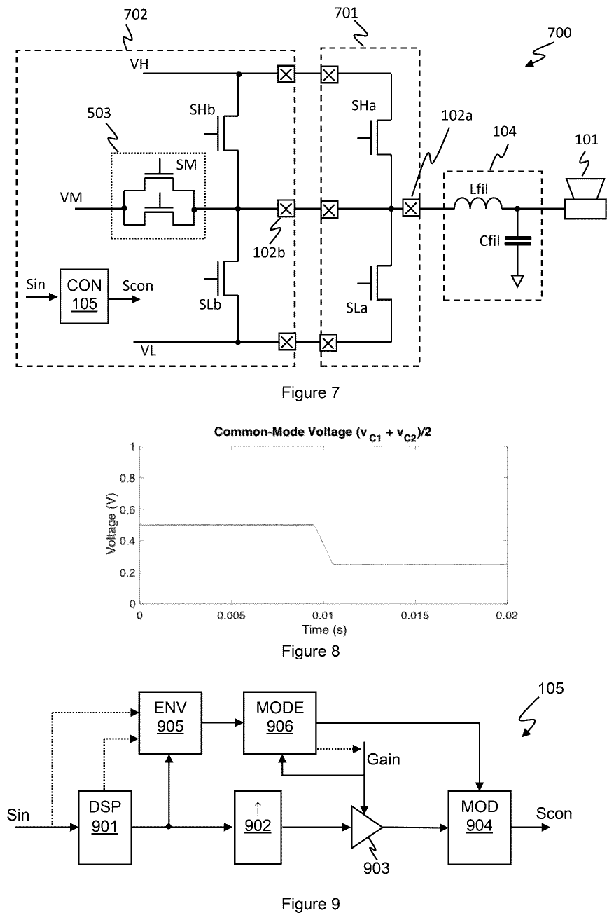

FIG. 7 illustrates one example of switching amplifier 700 which first and second ICs 701 and 702 to collectively provide a T-bridge output stage with a variable output resistance. Note that FIG. 7 shows, for clarity, the connections for only one side of the load 101, and the first and second ICs 701 and 702 may also have similar connections for the other side of the load. FIG. 7 illustrates that an output node 102a of the first IC 701 is connected, in use, to the load 101 via filter arrangement 104. The first IC 701 comprises a high side switch Sha and a low-side switch Sla for connecting the output node 102a to the high-side voltage VH or the low-side voltage VL respectively. These switches Sha and Sla may be the switches that will be used in continuous operation in in the first, high-level, mode of operation, as it is the switches that are used in the high-level mode of operation that may benefit most from being implemented in a material system such as GaN. The on-resistance of these switches may thus be configured to be relatively low and may not be controllably variable in use. A second IC 702, which may be implemented in a different material system to the first IC, e.g. in silicon, comprises a T-bridge arrangement connected to an output node 102b of the second IC, the T-bridge arrangement comprising a high-side switch SHb, low side switch SLb and a switch arrangement 503 such as illustrated in FIG. 5 arranged to provide an intermediate switch SM to an intermediate voltage VM. The second IC 702 also comprises a switch controller 105 for controlling operation of the switches of the T-bridge of the second IC 702 as well as the switches of the first IC 701.

In use, in continuous operation in the first mode of operation, the switch controller 105 can control switching of the switches SHa and SHb of the first IC (on both side of the load) with an appropriate duty-cycle to generate the desired drive voltage across the load. To provide operation in the first mode of operation, but with an increased output resistance so as to provide damping on a change to the first mode of operation, the switches SHb and SLb of the second IC 702 may be used instead of the corresponding switches of the first IC 701. The switches SHb and SLb of the first IB may be configured to provide a suitable on-resistance to provide damping. To provide operation in the second mode of operation, in this example the switch arrangement 503 of the second IC can be operated as the switch SM to the intermediate voltage VM, with the switch arrangement 503 being operated in the high-resistance on-state during a damping period following change to the second mode of operation and being operated in the low-resistance on-state thereafter for continued operation in the second mode.

The example of FIG. 7 thus allows for a conventional commercially available output bridge circuit to be used as the first IC 701, with the second IC providing the functionality of swapping between different modes of operation with a damping period.

### Gradual Movement of the Common-Mode Voltage

Another way of reducing the problem of ringing in the common-mode response on a change of mode, which may be applied in addition to or instead of applying increased damping, is to vary the common-mode in a more gradual fashion, e.g. to ramp the common-mode value over time.

The ringing response illustrated in FIG. 3 is in response to a relatively large step change in the common-mode voltage Vcmout applied to the output nodes 102-1 and 102-2, such as illustrated in FIG. 2. One way to reduce the ringing would be to vary this common-mode voltage Vcmout in a more gradual manner, i.e. in a relatively continuous manner over a period of time or via a series of smaller jumps in the common-mode voltage Vcmout. The general approach may be to control the common-mode voltage so as to reduce or remove any high-frequency component in the common-mode voltage.

The discussion in relation to FIG. 2 assumes that, in continuous operation in the first and second modes of operation, the quiescent signal level corresponds to a duty-cycle of 50% on each side of the load (i.e. the proportion of the switching cycle spent at high-side voltage VH or intermediate voltage as appropriate, with the rest of the switch cycle being spent at the low-side voltage VL) and that any variation in signal level results in equal and opposite changes in duty-cycle on each side of the load. This means that the quiescent signal level corresponds to each of the first and second output nodes 102-1 and 102-2 being driven to a voltage equal to VH/2 or VM/2 depending on the mode, and the differential signal is generated by varying the voltage at each of the first and second output nodes 102-2 and 102-2 by an equal and opposite amount. Put another way, the voltages at the first and second output nodes are respectively controlled to be, on average over the course of the switching cycle, equal to Vcmout+Vdrv/2 and Vcmout−Vdrv/2 respectively, where Vcmout is the common-mode voltage and Vdrv is the desired differential output voltage.

This operation is beneficial in that the common-mode voltage Vcmout applied to the output nodes 102-1 and 102-2 does not vary on a cycle-by-cycle basis in a given mode of operation i.e. the steady-state value of common-mode voltage in continuous operation in that mode is constant. The common-mode voltage Vcmout is generally controlled in the first mode to be half-way between the relevant switching voltages used in that mode, i.e. halfway between VH and VL, so that the full output range of differential output signal can be generated.

However, at the time that the amplitude of the input signal is low enough that the mode of operation can be changed from the first, high-level, mode to the second, low-level, mode, the full output range in the first mode of operation is not required. In this case, it would be possible to operate in the first mode with a value for the common-mode voltage Vcmout which is different to VH/2 and still be able to generate the full signal excursion.

Consider the example discussed above where VH is 48V, VM is 16V and VL is ground. In continuous operation in the first mode, the common-mode voltage Vcmout may be set as 24V so as to allow a differential drive signal Vdrv to be generated in the range of +48V to −48V. In continuous operation in the second mode the common-mode voltage Vcmout may be set as 8V. If the mode of operation were changed from the first mode of operation with a steady-state common-mode voltage of 24V to the second mode of operation with a steady-state common-mode mode voltage of 8V, this sudden jump in common-mode voltage could result in ringing, as discussed with reference to FIG. 3.

However, given the amplitude of the differential drive signal Vdrv would be lower than 16V in order for the change to the second mode of operation to occur, and this amplitude range can be achieved by operating in the second mode of operation with a common-mode voltage of 8V, it is noted that a differential drive signal Vdrv of this amplitude could also be achieved by operating in the first mode with a common-mode voltage Vcmout of 8V, i.e. the same common-mode voltage as used in the second mode.

In this case, rather than swap directly from operation in the first mode of operation with a steady-state common-mode voltage of 24V (i.e. VH/2) to operation in the second mode of operation with a steady-state common-mode voltage of 8V (i.e. VM/2), the change in mode may involve a transitional period which involves operating in the first mode with a gradual reduction, over time, in the common-mode voltage Vcmout from, in this example, 24V to 8V, and only then changing to operate in the second mode. The rate of change of the common-mode voltage during the transitional period may be selected with respect to the time constant of the common mode circuit so as to excite no, or only a limited amount of, ringing. In this example, there would thus be no substantial change in common-mode voltage on the change in mode at the end of the transitional period and thus the change in mode would be excite no significant ringing. Note damping, such as described above could be applied to suppress any ringing that does occur but moving the common-mode voltage during a transition period in this way may reduce the amount of damping required. An increased output resistance may also be applied during the transitional period to reduce power consumption.

FIG. 8 illustrates a plot of the common-mode voltage Vcmfil of the capacitor voltages for an example where a switching amplifier 100 such as illustrated in FIG. 1 was operated in the first mode switching between a high-side voltage VH and a low-side voltage VL, which is this plot are normalised to voltage values of 1 and 0 respectively. Initially the switching amplifier is operating in the first mode with a common-mode voltage Vcmout equal to 0.5, i.e. is modulating each of the output nodes 102-1 and 102-2 between VH and VL such that the quiescent signal level corresponds to a duty-cycle of 50% for each output node. During a transitional period, centred around 0.01 s in this example, the switching amplifier 100 continued to operate in the first mode but the common-mode voltage Vcmout applied to the output nodes 102-1 and 102-2 was gradually changed over a period of time, in this example to a common-mode voltage Vcmout of about 0.25. Essentially this can be seen as applying an equal, signal independent, offset to the duty-cycle for each of the output nodes 102-1 and 102-1 so as to maintain the correct average differential drive voltage Vdr over the course of the switching cycle but to vary the common-mode voltage Vcmout, with the offset being gradually increased over time. FIG. 8 shows that the common-voltage Vcmfil of the capacitors Cfil of the filter arrangement changes over time during this transitional period but there is no significant ringing, due to the gradual change in the common-mode voltage Vcmout.

For a change in mode from the second, low-level, mode to the first, high-level mode, a similar process could be followed but in reverse. That is, the switching amplifier 100 may be operated in the second mode and may be operated with a common-mode voltage Vcmout equal to VM/2. When a change in mode to the first mode is required, the switching amplifier may change to operating in the first mode and may operate in a transitional period immediately following the change in mode. At the start of the transitional period the switching amplifier 100 may be operated in the first mode, but with substantially the same value for the common-mode voltage Vcmout as was used in the second mode. During the transitional period, following the change of mode, the common-mode voltage Vcmout may be gradually increased to the desired value for continuous operation in the first mode, e.g. to VH/2 (where VL is ground).

For example, for the examples discussed above, where VH is 48V, VM is 16V and VL is ground, the steady-state common-mode voltage which is used in the second mode of operation may be VM/2=8V. At the time of the change to operation in the first mode, the switching amplifier may thus operate in the first mode with a common-mode voltage of 8V so there is no substantial change in the common-mode voltage Vcmout. During a transitional period, the switching amplifier may be operated in the first mode, but the common-mode voltage Vcmout may be gradually increased to a common-voltage of 24V. At the end of the transitional period the switching amplifier may continue to operate in the first mode with a steady-state common-mode voltage Vcmout, which allows for the full desired output range of differential drive signal Vdrv to be generated.

This transition from the second mode to the first mode, with a transitional period of operation in the first mode to move the common-mode voltage Vcmout to the desired level, e.g. VH/2, to be able to generate the desired full range of differential drive signal Vdrv does require some look-ahead or notice of an increase in signal amplitude which is sufficient to allow the mode to the be changed and the transitional period to be completed before the increase amplitude in signal needs to be output by the switching amplifier 100. The duration of the transitional period, and thus the rate at which the common-mode voltage Vcmout is changed during the transitional period and/or the amount of change in common-mode voltage which is achievable in the transitional period, may thus depend on the amount of look ahead which is available.

There are various ways such look-ahead may be implemented. For instance, in many switching amplifier designs there may be some inherent processing delay in a signal path of the amplifier that can be used to provide some look ahead.

FIG. 9 illustrates one example of selected components of one example of a switching controller 105 that could be implemented to control switching of a switching amplifier 100 such as illustrated in FIG. 1 and how some look ahead could be implemented.

FIG. 9 illustrates that the switching controller 105 may comprise a digital signal processor (DSP) 901 configured to receive the input signal Sin and apply some signal conditioning, for example to implement some protection and/or control functionality. The output of the DSP 902 may be interpolated by an interpolator 902 to increase the sample rate and some digital gain may be applied by a gain element 903. The resulting signal may be supplied to a modulator 904, which may, for example, comprise at least one PWM modulator configured to generate suitable switching control signals Scon for controlling the duty-cycles of the relevant switches of the T-bridges to generate the desired differential drive signal in the desired mode. The interpolation by the interpolator 902 may result in some propagation delay in this signal path. FIG. 9 thus illustrates that a signal could be tapped from the signal path upstream of the interpolation and used to provide some look-ahead for any required modes changes. The example of FIG. 9 illustrates that an envelope detector 905 may be arranged to receive the signal which is output from the DSP 901 and determine an envelope value for this signal, which may be supplied to a mode controller 906 which determines when a change in mode is required, and which may control the modulator 904 accordingly, although other arrangements such as peak detector or absolute value unit could be used in other examples. The mode controller 906 may also take account of any gain applied downstream of the interpolator 902.

FIG. 9 illustrates that the envelope detector 905 receives the signal output from the DSP 901, but in some cases the input signal to the DSP 901 could be used instead, which may provide further look-ahead, in which case the envelope detector 905 or mode controller 906 may also receive an indication of any gain applied by the DSP 901.

The amount of look-ahead may determine the possible duration of the transitional period, at least on a transition from the second, low-level, mode to the first, high-level mode. Ideally the amount of look-ahead may be sufficient to provide a duration for the transitional period that allows the common-mode voltage Vcmout to be moved by the desired amount (e.g. between VH/2 and VM/2 or vice versa) at a rate which is below the time constant of the common-mode circuit, and thus which excites no substantial ringing. However, this may not be the case for some implementations and in some applications the amount of look-ahead may not provide sufficient time to move the common-mode voltage by the whole desired amount with a sufficiently low rate of change. In some applications, the amount of look ahead could be increased by deliberately including some additional delay in the processing path, but in at least some applications this may be undesirable for latency reasons. In this case, moving the common-mode voltage as slowly as possible given the amount of look-ahead may still reduce the amount of ringing and/or moving the common-mode voltage over as much of the desired range as possible to minimise the amount of step-change in the common-mode voltage at the point of the change in mode may also reduce the amount of ringing.

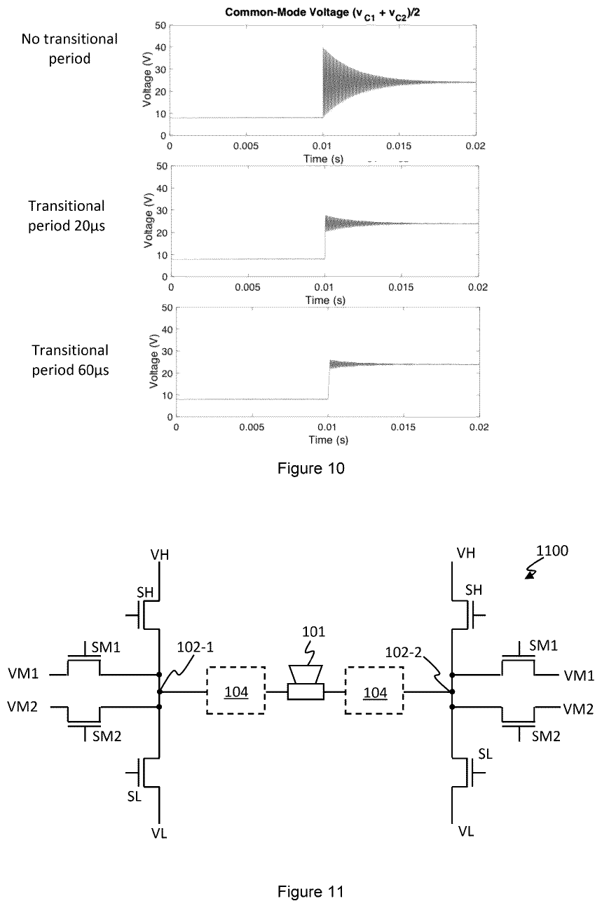

FIG. 10 illustrates waveforms of the common-mode voltage Vcmfil of the capacitor voltages for a switching amplifier 100 such as illustrated in FIG. 1 following a change in mode with and without a transitional period in which the common-mode voltage Vcmout is varied. The parameters of operation were the same as discussed for FIG. 3, and the waveforms illustrate the common-mode voltage Vcmfil following a change in mode from the second mode to the first mode. The top plot shows the common-mode voltage Vcmfil of the capacitor voltages without any transitional period being applied and the common-mode voltage Vcmout thus changing from 8V to 24V in a step change. Again, significant ringing as discussed with reference to FIG. 3 can be seen. The middle plot illustrates the common-mode voltage Vcmfil of the capacitor voltages where a transitional period of 20 μs was applied following the change to the first mode and where the common-mode voltage Vcmout is increased from 8V to 24V over that transitional period. It can be seen that this still excites some ringing, but the amount of ringing is significantly reduced compared to the case with no transitional period. The lower plot illustrates the common-mode voltage Vcmfil of the capacitor voltages where the duration of the transitional period was instead 60 μs. It can be seen that ringing of the common-mode voltage Vcmfil is further reduced.

Whilst, in some applications, the duration of the transitional period may be defined by the amount of look-ahead which is available, in some applications a longer transitional period may be implemented by limiting the amount of any change in signal amplitude which is allowed before the transitional period ends.

For example, consider that a look-ahead of 20 μs is available, but is desired to allow for a transitional period with a duration of 40 μs on a change in mode from the second, low-level, mode to the first, high-level, mode. In this case, the switching amplifier 100 may be configured to switch from the second mode to the first mode as soon as it is detected that a change in mode is required. The change in mode may occur with no substantial change in common-mode voltage Vcmout as discussed above and the common-mode voltage Vcmout may then be increased during a transitional period. In this case the duration of the transitional period may be set to be 40 μs. As the amount of look-ahead was only 20 μs, the change in signal amplitude that triggered the change in mode would ordinarily occur halfway through the transitional period. However, the switching amplifier may be configured to limit the amplitude of the differential drive signal until the end of the transitional period. Such limiting could be applied, for instance, by applying compression to the input signal Sin to limit the maximum amplitude when operating in the second mode, and only removing the compression at an appropriate time to correspond with the end of the transitional period. For a change in user or system-controlled gain, e.g. a change in volume that results in the need for a change in mode, the change in gain could be delayed until the end of the transitional period (or until the common-mode Vcmout has reached a level where the required signal amplitude can be generated). Referring back to FIG. 9, the mode controller 906 may therefore be configured to control some compression applied in the signal path, e.g. by DSP 901 and/or some gain applied, e.g. the gain applied by gain element 903.

Note that the discussion above has assumed that in the transitional period prior to a change in mode from the first mode to the second mode the common-mode voltage Vcmout is ramped from a first steady-state value, equal to that used in continuous operation in the first mode, say 24V to a second steady-state value which is equal to that used in continuous operation in the first mode, say 8V. This may be the preferred operation as it avoids any significant jump in common-mode voltage at the time of the change in mode, however in some cases it may be sufficient to ramp from the common-mode voltage Vcmout from the first steady-state value to a value which is closer to the second steady-state value (but need not be equal to the second steady-state value). Likewise, for a transitional period following a change in mode from the second to the first mode, the starting value of the common-mode voltage may not be exactly equal to the second steady-state value, and instead there could be some jump in common-mode at the time of the change in mode to an intermediate value, with ramping up to the first steady-state value over the transitional period.

In general, therefore, the switching amplifier may be controlled such that, for a change in mode of operation from a present mode to a new mode, in which a desired steady-state common-mode voltage for continuous operation in the present mode has a first value which is different to a second value of the desired steady-state common-mode voltage for continuous operation in the new mode, the amplifier is controlled such that common-mode voltage is controllably moved over time so that any step-change in common-mode at the point of the change in mode is less than the difference between the first and second values, and preferably as close to zero, or some acceptable change in common-mode voltage, as possible. This may involve moving the common-mode voltage in the present mode from the first value towards the second value and/or transitioning to the new mode with common-mode voltage closer to the first value. The common-mode voltage should preferably be moved at a rate that does not result in significant ringing, but which allows the required differential output signal to be generated without clipping in the relevant mode. However, in the event that the value of the common-mode voltage is not sufficient to allow the required differential output signal to be generated without clipping, compression may be applied to the input signal until such time as the common-mode voltage has varied enough.

### Setting the Common-Mode Voltage in Continuous Operation

The discussion above refers to the common-mode voltage Vcmout in continuous operation in the first mode being equal to (VH−VL)/2 and the common-mode voltage Vcmout in continuous operation in the first mode being equal to (VM−VL)/2. As discussed, setting the common-mode voltage Vcmout used in a given mode of operation as being midway between the two switching voltages used in the mode can be beneficial in terms of allowing the full range for differential drive signal when operating in a given mode.

However, in some applications it may not be necessary to implement the full output range in a given mode of operation. In which case it may, in some cases, be advantageous to set the common-mode voltage Vcmout which is used in continuous operation in that mode to some other value.

For example, for the examples discussed above, where VH is 48V, VM is 16V and VL is ground, the second mode may, as discussed, be used for generating a differential drive signal Vdrv with an amplitude up to 16V, and in this case the common-mode voltage Vcmout which is used in continuous operation in the second mode may be set to be 8V. However, if the second mode of operation were instead only used to generate a differential drive signal with an amplitude up to 8V, say, then the common-mode voltage Vcmout used in continuous operation in the second mode could actually be set anywhere in the range of 4V to 12V. In some applications, there may be advantages in setting the common-mode voltage which is used in continuous operation in the second mode to the value other than 8V, i.e. other than (VM−VL)/2.

For instance, setting the common-mode voltage Vcmout which is used in continuous operation in the second mode to a relatively high value may minimise the difference between the common-mode voltage used in continuous operation in the first and second modes respectively. For the examples discussed above, if the common-mode voltage Vcmout used in continuous operation in the first mode is 24V and the common-mode voltage Vcmout used in continuous operation in the first mode is 12V, this can reduce the change in common-mode voltage that occurs on a change in mode. This may reduce the amount of ringing if the mode is changed without a transitional period, and hence may reduce the amount of damping required and/or may reduce the amount by which the common-mode voltage Vcmout needs to be changed during a transitional period, which may allow for a slower rate of change for a given duration of transitional period.

Thus setting the common-mode voltage Vcmout which is used in continuous operation in the second mode to be greater than (VM−VL)/2, and ideally to be as high as possible may reduce the change in common-mode required on a change in mode which may reduce the amount of ringing even in the absence of any mitigation for the ringing, and may result in any mitigation applied, such as damping and/or use of a transitional period, having better performance.

The same principles would also apply to the common-mode voltage Vcmout which is used in continuous operation in the first mode. For instance, if the desired output range for the differential drive signal Vdrv was lower than + (VH−VL) to −(VH−VL) then it is the case that the common-mode voltage Vcmout used in continuous operation in the first mode could be lower than (VH−VL)/2 and using a lower common-voltage for continuous operation in the first mode could additionally or alternatively reduce the change in common-mode voltage required on a change in mode.

When the low-side voltage is ground there can additionally or alternatively be an advantage in terms of power supply noise in using a common-mode voltage than is lower than VH/2 or VM/2 depending on the mode of operation. The closer the common-mode voltage Vcmout is to ground, the greater the proportion of time that each output node 102-1 and 102-2 spends connected to ground during the switching cycle, and the ground supply may suffer from less power supply noise.

Setting the common-mode voltage Vcmout which is used in continuous operation in a given mode of operation to a value which not halfway between the relevant switching voltages in that mode of operation represents one aspect of the present invention in particular for a switching amplifier with a T-bridge on either side of the load, i.e. a switching amplifier where each of first and second output nodes may be selectively connected to any of three different switching voltages, a high-side voltage, a low-side voltage and an intermediate voltage.

Additional Modes and/or Voltage Levels

The discussion above has focused on the switching amplifier 100 being operable in two different modes, a first mode, in which the first and second output nodes 102-1 and 102-2 are each modulated between the high-side voltage VH and the low-side voltage VL, and a second mode, in which the first and second output nodes 102-1 and 102-2 are each modulated between the intermediate voltage VM and the low-side voltage VL. It will be understood that there is a possible third mode of operation which could be used, in which each of the first and second output nodes 102-1 and 102-2 is modulated between the high-side voltage VH and the intermediate voltage VM. This third mode of operation could generate a differential signal with a magnitude of up to |(VH−VM)|. This third mode of operation could, in some embodiments, be used in addition to or instead of the second mode of operation to provide an alternative or addition lower-level mode, particular if the intermediate voltage VM was not halfway between the high-side and low-side voltages VH and VL. For instance, for the example voltage values discussed previously, where VH=48V, VL is ground and VM is 16V, operating in the third mode could allow a differential signal to be generated in the range of +32V to −32V. The third ode could, therefore, be used as an intermediate-level mode in addition to the first and second modes.

It will be understood that it the third mode were used, and it was desired to allow a full range of differential signals to be produced in the range of 32V to −32V, the common-mode voltage Vcmout in continuous operation in the third mode may be set to be equal to 32V, i.e. to a value which is (VH−VM)/2 above VM. This is different to (and higher than) the common-mode voltage Vcmout used in continuous operation in either of the first and second modes and thus transitioning between continuous operation in the third mode to continuous operation in one of the first or second modes would also involve a change in the common-mode voltage Vcmout.

One or more of the techniques described above could be used to minimise any ringing as a result of the change in common-mode voltage on such a change in mode, e.g. some additional resistance could be applied to provide some damping, the common-mode voltages used in operation in the different modes may be set to be as close to one another as possible (if a full scale output in one or more of the modes is not required) and/or the common-mode voltage may be moved, during a transitional period before and/or after the change in mode, to reduce the amount of any step-change in common-mode at the point of the change in mode. However, in the case of moving the common-mode voltage in a transitional period, it will be understood that it would not be possible to swap directly from the third mode of operation to the second mode of operation in the presence of some differential signal content without some step-change in the common-mode voltage Vcmout. The lowest value of common-mode voltage Vcmout that could be achieved when operating in the third mode would be equal to VM, but this would correspond to each of the first and second output nodes 102-1 and 102-2 being switched to VM for the whole of the switching cycle, which doesn't allow for any differential signal content. Likewise, the highest value of common-mode voltage Vcmout that could be achieved when operating in the second mode would be VM, which again would correspond to each of the first and second output node 102-1 and 102-2 being switched to VM for the whole of the switching cycle, which again wouldn't allow for any differential signal content.

In some embodiments, therefore, it may preferable to swap between the third mode and second mode via a transitional period of operation in the first mode. For example, if the switching amplifier 100 were operating in the third mode, with a common-mode voltage Vcmout value suitable for continuous operation in the third mode, say equal to VM+(VH−VM)/2, and the amplitude of the input signal reduced to a level suitable for use in the second mode, the switching amplifier may initially swap from the third mode to the first mode, with the initial common-mode voltage value being controlled to provide no substantial step-change. The switching amplifier may then operate in the first mode for a transitional period in which the common-mode voltage Vcmout is changed to a level that corresponds to the desired common-mode voltage value for operation in the second mode, at which point the switching amplifier may swap to operating in the second mode. For the reverse transition, from the second mode to the first mode, there may likewise be a transitional period of operation in the first mode in which the common-mode value is changed from a value suitable use in the second mode to a value suitable for use in the third mode, before swapping to the third mode.

It should also be understood that a multi-level switching amplifier which is operable with more than three different switching voltages may also be operable in two or more different modes which may require different values of common-mode voltage (in continuous use in the relevant modes) and the principles of the present disclosure may be applied to mitigate the effect of any ringing that would be caused by a step-change in common-mode on a change in mode for amplifiers that are operable with more than three switching voltages.

For example, FIG. 11 illustrates one example of a switching amplifier 1100 (where similar components as discussed with reference to FIG. 1 are identified by the same reference numerals) where each the first and second output nodes 102-1 and 102-2 may be selectively connected to any of four different switching voltages, a high-side voltage VH via switch SH, a low-side voltage VL via switch SL or any of two different intermediate voltages VM1 and VM2, which are different to one another and are at voltage levels between VH and VL, via respective switches SM1 and SM2. It will be understood, however, that FIG. 11 illustrates just one possible switch arrangement for the switching amplifier 1100, and other arrangements may be implemented. In general there is a respective switching path, which may comprise one or more switches, for connecting the output node 102-1 and 102-2 to each switching voltage, and at least some parts of the switching paths for different switching voltages could be shared.

It will be noted that FIG. 11 also illustrates each of the switches as a single switch elements for clarity, but it will be understood that one or more of these switches could be implemented by switch arrangements such as described with reference to FIGS. 5a and 5b, and/or there could be parallel switching paths, e.g. to provide different resistances.

The switching amplifier 1100 may be operated such each of the first and second output nodes may be selectively modulated between any selected pair of these four different switching voltages. If the same pair of switching voltages are used for modulating both the first and second output nodes 102-1 and 102-1 in a given mode of operation, this means that there are six different possible modes of operation, i.e. where the pairs of voltages used as the switching voltages are: VH&VM1; VH&VM2, VH&VL; VM1&VM2; VM1&VL; and VM2&VL.

As an example, consider that VH=48V, VM1=16V, VM2=12V and VL=0V (ground). Table 1 below sets out the six different possible modes of operation that could possibly be used, based on the high and low switching voltage of each pair of switching voltages, and also illustrates the maximum magnitude of differential output voltage that could be generated by operating in the relevant mode. The table also illustrated the value of the common-mode voltage Vcmout that would be used to enable the full output range in that Mode.

TABLE 1

| | High | Low | | |
|---|---|---|---|---|
| | switching | switching | VDiff Max | |
| Mode | voltage | voltage | magnitude | Vcmout - for full range |
| Mode 1 | 48 | 0 | 48 | 24 |
| Mode 2 | 48 | 12 | 36 | 30 |
| Mode 3 | 48 | 16 | 32 | 32 |
| Mode 4 | 16 | 0 | 16 | 8 |
| Mode 5 | 12 | 0 | 12 | 6 |
| Mode 6 | 16 | 12 | 4 | 14 |

It can be seen that the common-mode value Vcmout is different in each of the modes of operation. In use, the switching amplifier 1100 may be controlled to swap between at least some of these modes of operation based on the amplitude of the input signal in a similar manner as discussed above. Again any one or more of the techniques described above could be used to minimise any ringing as a result of the change in common-mode voltage on such a change in mode.

It will also be understood that the extent to which the common-mode voltage Vcmout can be moved during a transitional period is limited by what the high and low switching voltages are, and the need to allow sufficient headroom above or below the common-mode voltage to reproduce the differential signal content without clipping. As discussed above in relation to the third possible mode of the switching amplifier 100 of FIG. 1, in some cases if the common-mode is to be moved in a transitional period, to reduce the amount of any step-change in common-mode voltage on a change of mode, in some cases it may be beneficial to swap from a present mode of operation to a new mode of operation via a differential transitional mode of operation, where the mode used in the transitional period has a sufficient range to be able to move the common-mode voltage without clipping.

For instance, in a transition (in either direction) between Mode 6 and Mode 5 as listed in table 1, it may not be practical to move the common-mode voltage in either of these modes to a value that could result in no step-change on a direct transfer between these modes, as this would require the common-mode voltage value to be 12V in both modes, which not allow for any differential signal content. However, the switching amplifier could, for example, operate in Mode 4 (or Mode 1 if necessary) for a transitional period to move the common-mode voltage value from 14V to 6V or vice-versa. Likewise, a transition (in either direction) between Mode 4 and Mode 3 may involve a transitional period of operation in Mode 1. However, some transitions between modes may not require use of a transitional mode and instead a transitional period of operation in the present mode or the new mode may allow for the common-mode voltage to be moved appropriately, for instance a transition between Mode 2 and Mode 3, or any transition to or from Mode 1. For a transition between any two selected modes (which need not be adjacent modes in table 1), it can be whether operation in a transitional mode would be beneficial or not.

Embodiments thus apply generally to BTL multilevel switching amplifiers operable in different modes with different switching voltages, in which a transition from continuous operation in one mode to a continuous operation in a different mode may result in a change in value of the common-mode of the output voltage.

### Modulator Design

Controllably varying the common-mode voltage Vcmout used in a given mode of operation, either on a temporary basis during a transitional period or to control the common-mode voltage value used in continuous operation, does mean that the conventional AD modulation control described with reference to FIG. 2, i.e. where the output nodes 102-1 and 102-2 are modulated in antiphase with one another, may no longer be appropriate for the switching amplifier. In particular, for conventional AD modulation, as the modulation of the output nodes 102-1 and 102-2 is in antiphase, a single modulator may be used for generating suitable PWM control signals for controlling the modulation on both sides of the load, with the switching control signals used for controlling switching on one side of the load being inverted to control the switching on the other side of the load. However, where the common-mode voltage is controlled as described above, the switching of the two output nodes 102-1 and 102-1 are no longer in antiphase and separate modulator control signals are needed for controlling modulation on each side of the load.

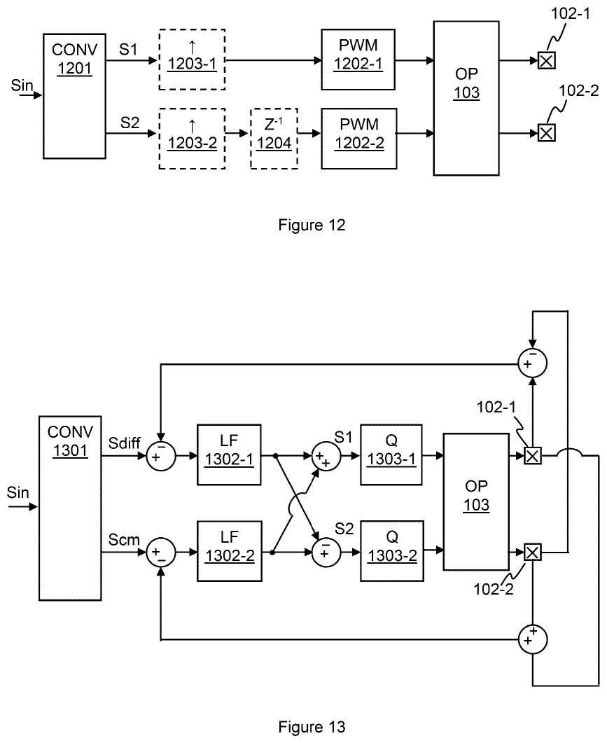

FIG. 12 illustrates one example of a possible modulator arrangement that could be used to drive switching on either side of load for a switching amplifier such as illustrated in FIG. 1 or FIG. 11. FIG. 12 illustrates that the input signal Sin may be input to a converter 1201 which converts the input signal Sin into two signal components S1 and S2, where S1 has a value that corresponds to Vcmout+Vdrv/2 and S2 has a value that corresponds to Vcmout-Vdrv/2, where Vdrv is the desired differential drive signal value based on the input signal Sin. The signal components S1 and S2 are each provided to respective PWM modulators 1202-1 and 1202-2 for generating the switch control signals for controlling the relevant switches of the output stage 103 connected to the relevant output node 102-1 or 102-2.

Optionally, the signals S1 and S2 may be interpolated by respective interpolators 1203-1 and 1203-2 and a delay 1204 applied to one of the signals, so as to provide a half cycle delay between the two signals. This may be advantageous in providing balancing of the PWM control signals.

The converter 1201 illustrated in FIG. 12 may thus control the value of the common-mode voltage Vcmout used in the different modes of operation and/or any variation of the common-mode voltage Vcmout applied during a transitional period. The converter 1201 may thus provide at least some of the functionality of the mode controller 905 discussed with reference to FIG. 9, and/or may be responsive to such a mode controller.

FIG. 13 illustrates an alternative modulator arrangement that may implemented to control the output stage 103 of the switching amplifier 100 or 1100. In the example of FIG. 13 a converter 1301 again receives the input signal Sin and divides it into two signal components, but in this example the two signal components are a differential component Sdiff and a common-mode component Scm. A feedback signal indicative of the differential output is subtracted from this differential signal component Vdiff to provide an error signal indicative of any error in the differential output signal. In the example of FIG. 12, this feedback signal is derived from the differential voltage between the output nodes 102-1 and 102-2, but other feedback arrangements could be used. The differential error signal is filter by a loop filter 1302-1.

Similarly, a feedback signal of the sum of the output voltages, in this example derived from the output nodes 102-1 and 102-2, is subtracted from this common-mode signal component Vcm to provide an error signal indicative of any error between the desired and actual common-mode output signal, which is filtered by a loop filter 1302-2. The differential error signal is subtracted from the common-mode signal in one signal path, whilst the common mode signal is separately added to the differential signal in the other signal path to provide first and second signal components S1 and S2 related to Vcmout+Vdrd/2 and Vcmout−Vdrv/2, which are then quantized by respective quantizers 1303-1 and 1303 to drive the respective T-bridges of the output stage 103 on each side of the load.

In the arrangement of FIG. 13, the control loop for the differential signal component is thus separate to the control loop for the common-mode signal component. The control loop for the differential signal components, which is the signal content of interest, may be implemented as a relatively high-performance loop, e.g. a loop with a relatively high SNR (signal-to-noise ratio) and/or a relatively low level of distortion, e.g. a relatively low THD (total harmonic distortion). However, the common-mode control loop may be implemented as a relatively lower performance control loop, e.g. with a lower SNR and/or THD. Implementing the common-mode control loop as a lower-performance control loop can allow for savings in circuit area, cost and/or power consumption in use compared to an arrangement such as illustrated in FIG. 12 which may require both the PWM modulators 1203 to be implemented as part of a high-quality control loop to provide a desired performance, as in the example of FIG. 2 there is signal content of interest in each of the separate signal components S1 and S2. Preferably, the common-mode control loop and control loop for the differential signal components will be configured to have substantially the same latency and will preferably be switched at the same switching frequency as one another.

### Correcting for Mismatch

As noted above, one problem that can arise with a change in common-mode voltage Vcmout is common-mode to differential conversion in the output path, e.g. due to the filter arrangement 104. Ensuring the components, such as the capacitors and/or inductors, used for the filter arrangements 104 are accurately matched to one may require the use of relatively expensive components. In practical implementations it may therefore be expected that there is some mismatch between the filter arrangements on either side of the load, e.g. the capacitance values and/or inductance values may differ between the filter arrangements on each side of the load. Thus, referring back to FIG. 1, the filter arrangement 104 connected between the first output node 102-1 and the load may have a first transfer characteristic T1 and the filter arrangement 104 connected between the second output node 102-2 and the load may have a second transfer characteristic T2, where the first transfer characteristic T1 is different to the second transfer characteristic T2.

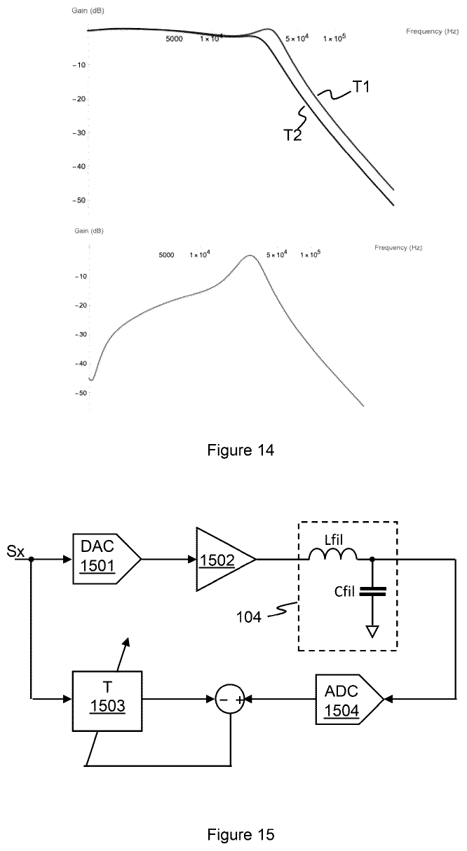

FIG. 14 illustrates this issues. The top plot of FIG. 14 illustrates an example of a switching amplifier 100 such as illustrated in FIG. 1 and illustrates one example of transfer characteristics T1 and T2 for the filter arrangements 104 on each side of the load which differ from one another. The lower plot illustrates the resultant common-mode to differential transfer function.

For conventional AD modulation with a substantial fixed common-mode voltage Vcmout, this difference in transfer function would not be a significant issue for the common-mode voltage component and may lead to some offset that could be readily compensated for. However, if the common-mode voltage is varied in use, for instance by swapping between the first and second modes of operation or, in particular, by varying the common-mode voltage Vcmout over a period of time in a transitional mode, this could result in common-mode to differential conversion which could degrade performance.

In some embodiments therefore some compensation for the common-mode to differential conversion may be applied.

To determine the compensation to be applied, the transfer function on each side of the load may be determined, e.g. the transfer characteristic of the filter arrangement and other components of the relevant output path. The transfer characteristic could, for example, be determined during system identification. As will be understood by one skilled in the art, system identification is a process that may be performed to characterize or model a particular system. System identification may be initially performed as part of a testing and evaluation stage of device fabrication and may involve operating at least part of the device under test with defined stimuli and/or system identification can applied within a device in use, for instance as part of calibration process performed on start-up and/or periodically in use. Performing system identification in operation of the device may allow for any changes due to operating conditions such as temperature and any aging of the components to be taken into account.

FIG. 15 illustrates one example how the relevant transfer function of the filter arrangement 104 could be determined during system identification. A test signal Sz is input to the filter arrangement 104, e.g. via digital-to-analog converter 1501 and amplifier 1502. The test signal is also applied to an adaptive filter 1403 with a transfer function T* intended to match the transfer function of the filter arrangement 104 under test. The actual output from the filter arrangement is compared to the output from the adaptive filter 1501 and the filter coefficients are adjusted to try to minimise the error, at least across the signal frequency band of interest. The system adaptation will typically be done via a LMS (least means squares) approach or perhaps a few cycles of RLS (recursive least squares) and hence the output from the filter will may be digitised by ADC 1504. This ADC 1503 need only have bandwidth over the audio band and has no latency requirements since the relevant signal will only be used for system identification rather than fed back in a linear sense.

Once the transfer functions T1* and T2* for each filter arrangement has been determined, suitable compensation can be determined. In some embodiments, the inverse of the relevant transfer function may be determined and used as the compensation for the appropriate output path. In this case the compensation should be the inverse of the determined transfer function for the path to which the compensation is applied, at least over the signal frequency band of interest, the compensation functions do not need to be the inverse of the transfer functions out-of-band.

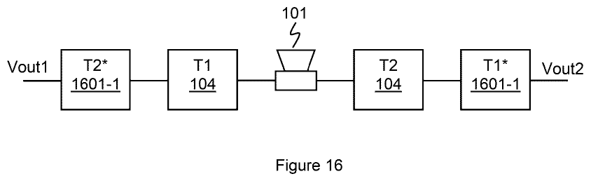

In some embodiments, the transfer function for the output path on one side of the load is used as the compensation applied to the output path on the other side of the load. FIG. 16 illustrates this approach and illustrates that the filter arrangement 104 on a first side of the load has a transfer characteristic T1 and the filter arrangement 104 on the second side of the load has a transfer characteristic T2. Compensation is applied by applying the determined transfer function T2* to the first side of the load and applying the determined transfer function T1* to the second side of the load. This avoids needing to invert the transfer function and also avoids unbalancing the delay on either side of the load.

In any case the compensation can be applied by any suitable filter arrangement in the respective signal path of the switching amplifier, for instance an adaptive filter of the like. Applying compensation in this way can substantially avoid any issues of common-mode to differential conversion.

### GENERAL EMBODIMENTS

Embodiments of the present disclosure thus relate to switching amplifier operable in different modes wherein at least switching voltage is different in the modes of operation and the common-mode voltage may be different in continuous operation in the different modes. Embodiments relates to methods and apparatus for mitigating from the effects of a change in common-mode voltage on a change in mode.

Embodiments may be implemented in a host device, especially a portable and/or battery powered host device such as a mobile computing device for example a laptop, notebook or tablet computer, or a mobile communication device such as a mobile telephone, for example a smartphone. The device could be a wearable device such as a smartwatch. The host device could be a games console, a remote-control device, a home automation controller or a domestic appliance, a toy, a machine such as a robot, an audio player, a video player. It will be understood that embodiments may be implemented as part of a system provided in a home appliance or in a vehicle or interactive display. There is further provided a host device incorporating the above-described embodiments.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

As used herein, when two or more elements are referred to as “coupled” to one another, such term indicates that such two or more elements are in electrical, mechanical, or electromechanical communication, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

1. A controller for controlling a switching amplifier to modulate voltages at first and second output nodes so as to drive a load connected between said first and second output nodes with a differential drive signal based on an input signal, wherein:
the controller is configured to control the switching amplifier to selectively operate in at least a first mode or a second mode, wherein in each of the first and second modes, the first and second output nodes are modulated between switching voltages with a controlled duty-cycle and at least one of the switching voltages is different in the first mode compared to the second mode;
the controller is configured to control the mode of operation based on the input signal such that the switching amplifier can dynamically swap between the first and second modes;
the controller is configured such that, in steady-state operation in the first mode a common-mode voltage applied to the first and second output nodes has a first value and in steady-state operation in the second mode a common-mode voltage applied to the first and second output nodes has a second value, different to the first value; wherein at least one of first values and the second values is not equal to a voltage which is halfway between the switching voltages used in that mode.

2. The controller of claim 1 wherein:
in the first mode, the first and second output nodes are modulated between first and second switching voltages; and
in the second mode the first and second output nodes are selectively modulated between said first switching voltage and a third switching voltage, wherein the third switching voltage is an intermediate voltage between the first and second switching voltages.

3. The controller of claim 2 wherein the controller is configured such that the second value is closer to the first value than a value which is halfway between the first and third switching voltages.

4. The controller of claim 2 wherein the controller is configured such that the first value is closer to the second value than a value which is halfway between the first and third switching voltages.

5. The controller of claim 2 wherein the first switching voltage is ground, the second switching voltage is a high-side voltage VH and the third switching voltage is an intermediate voltage VM and the controller is configured such that the first value of the common-mode voltage applied to the first and second output nodes in steady-state operation in the first mode of operation is equal to VH/2 and the second value of the common-mode voltage applied to the first and second output nodes in steady-state operation in the second mode of operation is greater than VM/2.

6. The controller of claim 1 wherein the controller is further configured, during a transitional period of operation in the first mode to controllably vary the common-mode voltage applied to the first and second output nodes away from the first value.

7. The controller of claim 6 wherein, during the transitional period of operation in the first mode the controller is configured to ramp the common-mode voltage applied to the first and second output nodes from the first value to the second value or vice versa.

8. A switching amplifier circuit comprising the controller of claim 2 and an output stage.

9. The switching amplifier circuit of claim 8 wherein the output stage comprises a respective bridge arrangement for each of the first and second output nodes, the bridge arrangement comprising a first switch for connecting the respective first or second output node to the first switching voltage, a second switch for connecting the respective first or second output node to the second switching voltage and a third switch for connecting the respective first or second output node to the third switching voltage.

10. A controller for controlling a switching amplifier to modulate voltages at first and second output nodes so as to drive a load connected between said first and second output nodes with a differential drive signal based on an input signal, the controller being selectively operable in at least first and second modes, wherein:
the first mode comprises modulating the first and second output nodes between switching voltages defining a first voltage range,
the second mode comprises modulating the first and second output nodes between switching voltages defining a second voltage range, different from the first voltage range, and
wherein in at least one of the modes, the controller is configured to control said modulation of the first and second output nodes such that a common mode voltage at the first and second output nodes is spaced from the midpoint of the voltage range for that mode.
